(19) United States
(12) Patent Application Publication
(10) Pub. No.: US 2025/0383414 A1
(43) Pub. Date: Dec. 18, 2025

(54) TUNNEL MAGNETORESISTANCE ELEMENT AND SENSOR HAVING INCREASED MEASUREMENT RANGE

(71) Applicant: Allegro MicroSystems, LLC, Manchester, NH (US)

(72) Inventors: Salim Dounia, Grenoble (FR); Andrey Timopheev, Vif (FR); Nikita Strelkov, Meylan (FR)

(73) Assignee: Allegro MicroSystems, LLC, Manchester, NH (US)

(21) Appl. No.: 18/740,749

(22) Filed: Jun. 12, 2024

(51) Int. Cl. G01R 33/09; G01R 33/00; H01F 1/055

(52) U.S. Cl. CPC G01R 33/098; G01R 33/0005; G01R 33/096; H01F 1/055

(57) ABSTRACT

The present disclosure concerns a tunnel magnetoresistance (TMR) element comprising a tunnel barrier layer sandwiched between a reference layer having a pinned reference magnetization and a sense layer having a sense magnetization that is orientable relative to the fixed reference magnetization in the presence of an external magnetic field. The sense magnetization comprises a stable vortex configuration having a vortex core magnetization polarity that is reversed when a vortex core polarity switching field is applied on the TMR element. The TMR element further comprises a shifting layer adjacent to the sense layer, the shifting layer having a shifting magnetization, the shifting layer being configured to induce a stray field on the sense layer and increases the vortex core polarity switching field. The present disclosure further concerns a TMR sensor comprising a plurality of the TMR elements. The TMR element and TMR sensor have improved robustness and field of application.

### FIELD

The present invention concerns a tunnel magnetoresistance element and tunnel magnetoresistance sensor for measuring an external magnetic field. More particularly, the present invention concerns a tunnel magnetoresistance element and sensor for measuring an external magnetic field along an out-of-plane axis.

### BACKGROUND

A tunnel magnetoresistance (TMR) sensor utilizing a TMR element provides high magnetic sensitivity, low power consumption, and smaller size by comparison to other magnetic technologies such as Hall, AMR, and GMR. A TMR element is a thin-film element with a structure in which a barrier layer made of a thin insulator is sandwiched between two ferromagnetic layers (typically a free layer and a pinned layer). Although the magnetization direction of the pinned layer is fixed, the magnetization direction of the free layer changes according to the external magnetic field direction. The electrical resistance of the TMR element changes along with this change in the free layer. The electrical resistance becomes the smallest when the magnetization directions of the pin layer and free layer are parallel, causing a large current to flow into the barrier layer. When the magnetization directions are antiparallel, the resistance becomes extremely large, and almost no current flows into the barrier layer.

The sensitivity axis, working magnetic field range, and linearity of the TMR sensor can be determined by modifying the arrangement of the TMR element and layout of the TMR sensor.

The free layer can comprise a vortex configuration whereby the magnetization curls in a circular path along the edge of the sense layer. Compared to a magnetoresistive sensor element based on a saturated sense layer, a magnetoresistive sensor elements comprising a vortex configuration in the sense layer provides much wider magnetic field range and better linearity at the same time. The vortex configuration provides a linear and non-hysteretic behavior in a large magnitude range of the external magnetic field. The vortex configuration is advantageous for magnetic sensor applications.

A TMR element having an out-of-plane sensitivity axis and where the free layer comprises a vortex configuration has typically a non-negligible hysteresis that impacts the TMR sensor performances, such as reduced accuracy, reproducibility, and reduced field range measurement. Moreover, the vortex core polarity switching field decreases with increasing temperature, resulting in a decrease of the TMR sensor measurement range.

### SUMMARY

The present disclosure concerns a TMR element comprising a tunnel barrier layer sandwiched between a reference layer having a pinned reference magnetization and a sense layer having a sense magnetization that is orientable relative to the fixed reference magnetization in the presence of an external magnetic field. The sense magnetization comprises a stable vortex configuration having a vortex core magnetization polarity that is reversed when a vortex core polarity switching field is applied on the TMR element. The TMR element further comprises a shifting layer adjacent to the sense layer, the shifting layer having a shifting magnetization, the shifting layer being configured to induce a stray field on the sense layer and increases the vortex core polarity switching field.

In an embodiment, the magnetization direction of the vortex core is along the out-of-plane axis substantially perpendicular to the plane of the sense layer. The reference layer and the shifting layer have a perpendicular magnetic anisotropy such that the reference magnetization and the shifting magnetization are oriented out-of-plane.

In an embodiment, the reference layer comprises a reference SAF structure including a first reference sublayer having a first reference magnetization, a second reference sublayer having a second reference magnetization, and a reference coupling layer between the first and second reference sublayers. The coupling layer is configured to produces an antiferromagnetically coupling between the first and second reference magnetization such that the second reference magnetization remains antiparallel to the first reference magnetization.

The present disclosure further concerns a TMR sensor comprising a plurality of the TMR elements.

The TMR element and TMR sensor have improved robustness and field of application.

### BRIEF DESCRIPTION

The foregoing features may be more fully understood from the following description of the drawings. The drawings aid in explaining and understanding the disclosed technology. Since it is often impractical or impossible to illustrate and describe every possible embodiment, the provided figures depict one or more illustrative embodiments. Accordingly, the figures are not intended to limit the scope of the broad concepts, systems and techniques described herein. Like numbers in the figures denote like elements.

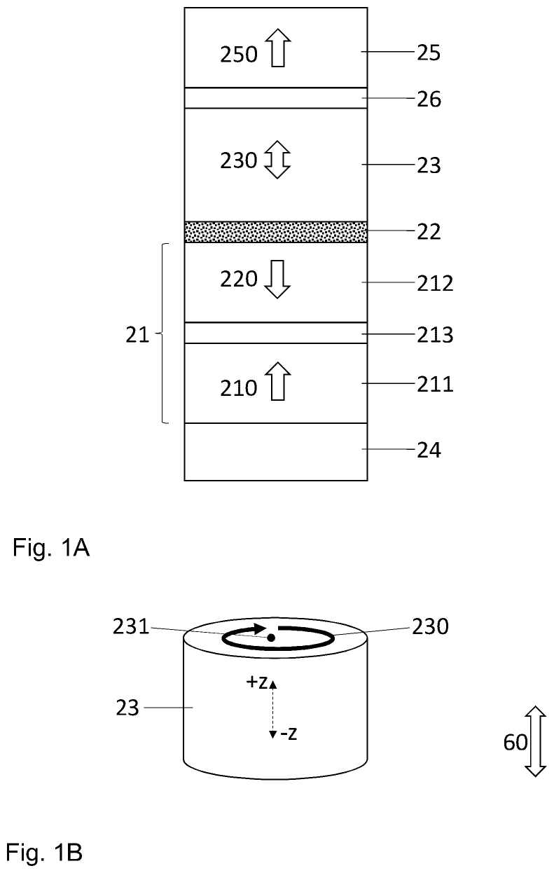

FIG. 1A shows a TMR element comprising a shifting layer and a sense layer, according to an embodiment;

FIG. 1B shows a detailed view of the sense layer with a sense magnetization having a vortex configuration;

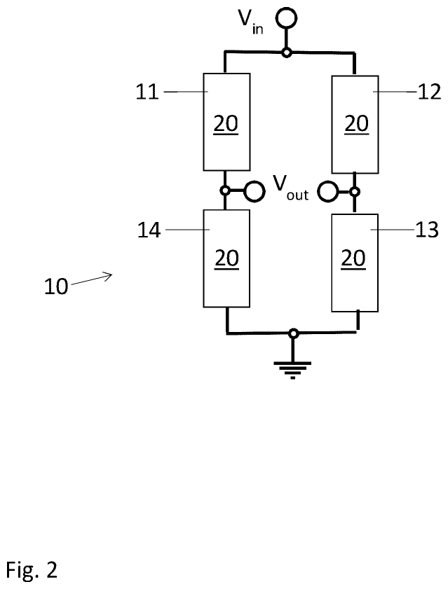

FIG. 2 illustrates a TMR sensor comprises a plurality of TMR elements arranged in a full-bridge configuration;

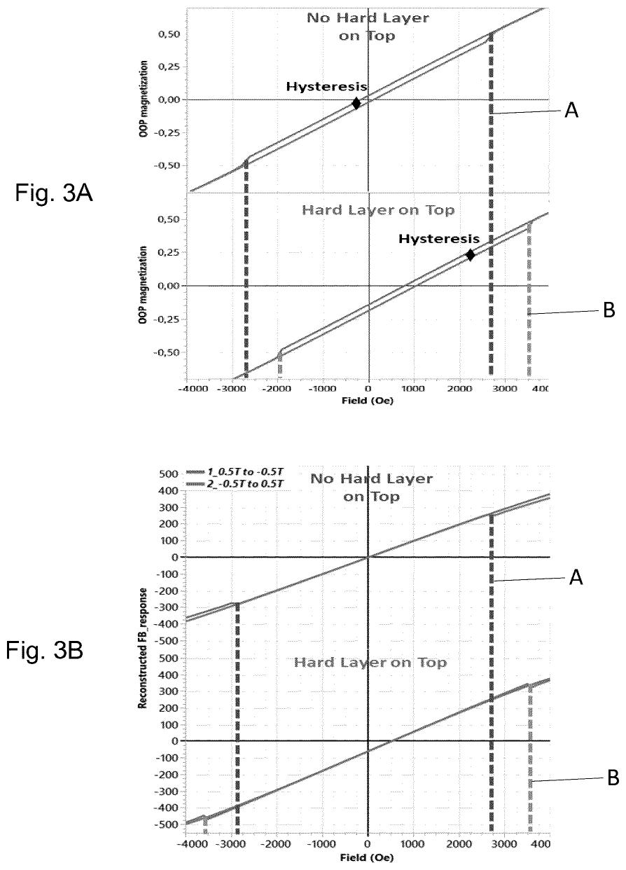

FIG. 3A shows a graph comparing the magnetization as a function of the external magnetic field for the TMR element in the absence of the shifting layer (curve A) and in the presence of the shifting layer (curve B);

FIG. 3B compares the response of the TMR sensor in a full bridge configuration without the shifting layer (curve A), and with the shifting layer (curve B); and

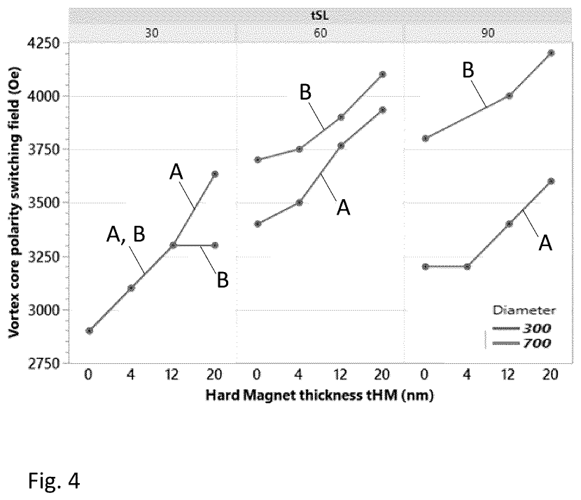

FIG. 4 reports the vortex core polarity switching field as a function of the thickness of the shifting layer for TMR elements having a lateral size of 300 nm (curves A) and of 700 nm (curves B).

### DETAILED DESCRIPTION

FIG. 1A shows a TMR element 20 according to an embodiment. The TMR element 20 comprises a tunnel barrier layer 22 sandwiched between a reference layer (pinned layer) 21 having a pinned reference magnetization and a sense layer (free layer) 23 having a free sense magnetization 210, 220 that is orientable relative to the fixed reference magnetization 230 in the presence of an external magnetic field 60.

Preferably, the reference layer 21 comprises a reference SAF structure including a first reference sublayer 211 having a first reference magnetization 210, a second reference sublayer 212 having a second reference magnetization 220, and a reference coupling layer 213 between the first and second reference sublayers 211, 212. The second reference sublayer 212 can be in contact with the tunnel barrier layer 22. The coupling layer 213 is configured to produces an antiferromagnetically coupling (a RKKY coupling) between the first and second reference sublayer 211, 212 such that the second reference magnetization 220 remains antiparallel to the first reference magnetization 210.

The sense magnetization 230 comprises a stable vortex configuration rotating in a circular path along the edge of the sense layer 23 and around a vortex core 231 (see FIG. 1B), reversibly movable in accordance with the external magnetic field 60.

The obtention of a vortex configuration in the sense layer 23 depends on a number of factors, including materials properties of the sense layer 23. Generally, the vortex configuration is favored (at zero applied field) by varying the aspect ratio of the thickness on the diameter of the sense layer 23.

For example, the sense layer 23 can have a thickness that is greater than 15 nm. For example, the sense layer can have a thickness between 15 nm and 80 nm or between 15 nm and 100 nm.

In an embodiment, the TMR element 20 has a lateral dimension L between 200 nm and 5000 nm. The TMR element 20 has an aspect ratio (thickness T of the TMR element 20 to half the lateral dimension L/2) between 0,005 μm and 2 μm.

FIG. 1B shows a detailed view of the sense layer 23 with the vortex configuration of the sense magnetization 230. The vortex configuration is characterized by its polarity. The magnetization of the vortex core 231 (vortex core magnetization polarity) varies in accordance with the external magnetic field 60 along an out-of-plane axis (indicated by the direction arrow ±z in FIG. 1B), i.e., substantially perpendicular to the plane of the sense layer 23. The vortex core magnetization polarity can be oriented in an upward direction (i.e., toward the direction +2) or in a downward direction (i.e., toward an opposite direction −z). The size of the vortex core increases or decreases in the direction +z or −z when the magnitude of the external magnetic field 60 increases or decreases, respectively. The vortex core magnetization polarity can be reversed (between direction z and −z) when a predetermined magnetic field (vortex core polarity switching field) is applied on the TMR element 20.

In one aspect, the reference and sense layers 21, 23 comprise, or are formed of, a ferromagnetic material including one or several transition metals such as a cobalt (Co), iron (Fe) or nickel (Ni) based alloy, and preferentially a CoFe, NiFe or CoFeB based alloy. The transition metals can be layered or codeposited.

Each of the first and second reference sublayers 221, 212 can comprise a CoFe, CoFeB or NiFe alloy and have a thickness typically comprised between about 0.5 nm and about 4 nm. The reference coupling layer 213 can comprise a non-magnetic material selected from a group comprising at least one of: ruthenium (Ru), chromium (Cr), rhenium (Re), iridium (Ir), rhodium (Rh), silver (Ag), copper (Cu), and yttrium (Y). Preferably, the coupling layer 232 comprises ruthenium and has a thickness typically included between about 0.4 nm and 2 nm, preferably between 0.6 nm and about 0.9 nm, or between about 1.6 nm and about 2 nm.

The tunnel barrier layer 22 comprises, or is formed of, an insulating material. Suitable insulating materials include oxides, such as aluminum oxide (e.g., Al₂O₃) and magnesium oxide (e.g., MgO). The thickness of the tunnel barrier layer 22 can be in the nm range, such as from about 1 nm to about 10 nm. Large TMR for example of up to 200% can be obtained for the magnetic tunnel junction 2 comprising a crystalline MgO-based tunnel barrier layer 22.

The TMR element 20 further comprises an electrode layer 24 comprising electrically conductive material in direct contact with the reference layer 21. The electrode layer 24 can comprise an electrically conductive strip or line.

The TMR element 20 further comprises a shifting layer 25 adjacent to the sense layer 23. The shifting layer 25 has a shifting magnetization 250 and is configured to induce a stray field that shifts the vortex core polarity switching field of the vortex configuration in the sense magnetization 230 toward higher fields.

The specific switching field at which the vortex core 231 is switched can be increased when the shifting layer 25 is added to the TMR element 20, adjacent to the sense layer 23.

The shifting layer 25 can be made of a hard magnetic material (i.e. stable in high magnetic fields), for example of a highly coercive material.

In sone embodiments, the hard magnetic material can comprise, or may be made of, a perpendicular ferrimagnetic alloy including at least a rare earth and at least a transition metal. For example, the rare earth can comprise Tb, Gd, Sm and TM and the transition metal can comprise Co, Fe, CoFe.

Alternatively, the hard magnetic material can comprise, or may be made of, a perpendicular ordered alloy, or a multilayered material comprising 3d-4d metals (such as Co, Fe, CoFe, Ni, Pt, Pd, Au, Ag) exhibiting perpendicular magnetic anisotropy. For example, the shifting layer 25 can comprise Co/Pt, Co/Pd, or Co/Ni multilayers.

Alternatively, the hard magnetic material can comprise, or may be made of, a L1₀ perpendicular ordered magnetic alloy. Such alloy may include an alloy of CoPt or FePt type.

Alternatively, the hard magnetic material can comprise, or may be made of, a permanent magnet based on a rare earth material. For example, 1-5 or 2-17 type alloy (such as SmCo) or RE₂Fe₁₄B type alloy (where RE can be Nd, Dy, Pr, etc.).

The above hard magnetic materials can comprise exchange decoupled grains obtained, for example, by inserting in the alloy a small amount of Cr, C, Cu, V, or an oxide. For example, the hard magnetic material can include any one, alone or in combination, of: CoCrPt, FePt—TiO₂, FePt—SiO₂, FePt—C, CoPt, NdFEB, or SmCo.

Alternatively, the hard magnetic materials can comprise, or may be made of, an antiferromagnetic material. The antiferromagnetic material can be made of IrMn and have a thickness between 2 nm and 20 nm, or PtMn or FeMn and have a thickness up to 30 nm. Alternatively, the antiferromagnetic material can be made of any one of: PdMn, CrPdMn, NiMn, CuMnAs, Mn₃Sn, Mn₂Au, Cr₂O. The antiferromagnetic material can have a blocking temperature between 150° C. and 300° C.

The TMR element 20 can further comprise a spacing layer 26 between the shifting layer 25 and the sense layer 23. The spacing layer 26 is configured to regulate the coupling strength between the shifting layer 25 and the sense layer 23. The spacing layer 26 can be configured such that the interfacial coupling is between −1 to +1 erg/cm². The spacing layer 26 can comprise, or may be made of, any one, alone or in combination, of: Ru, W, Ir, Ta etc. The spacing layer 26 should not be in contact with the reference layer 21.

In an embodiment, the shifting layer 25, spacing layer 26, sense layer 23, reference layer 21 are arranged in this order.

In a preferred embodiment, the magnetization direction of the vortex core 231 is along the out-of-plane axis substantially perpendicular to the plane of the sense layer. The reference layer 21 and the shifting layer 25 have a perpendicular magnetic anisotropy such that the reference magnetization 210, 220 and the shifting magnetization 250 are oriented out-of-plane.

In an embodiment, a TMR sensor 10 comprises a plurality of the TMR elements 20. The TMR elements 20 of the TMR sensor 10 can be electrically connected in parallel or in series via a non-magnetic electrically conductive electrode, strip, or line.

In some embodiments, the TMR sensor 10 comprises a plurality of the TMR elements 20 arranged in a full-bridge or half-bridge configuration comprising a plurality of sensing branches, where each sensing branch can comprise one or a plurality of TMR elements 20.

In the example of FIG. 2, in the TMR sensor 10 comprises a full-bridge configuration comprising four sensing branches 11-14, each sensing branch including one TMR element 20. The two TMR elements 20 within each branch 11, 12 have opposite programming directions of the pinned reference magnetization 210, 220 and of the shifting magnetization 250.

In an embodiment, a programming method of the TMR sensor 10 can comprise, programming the TMR element 20 such that the shifting magnetization 250 is oriented in the same out-of-plane direction (positive or negative z-direction) as the reference magnetization 210, 220. This generates a stray field that shifts magnetization curve of the sense magnetization 230. This results in the vortex core polarity switching field being switched at higher fields (negative or positive) compared to a TMR element 20 without the shifting layer 25.

In another embodiment, the shifting layer 25 is made of IrMn and has a thickness between 2 nm and 20 nm. The programming method of the TMR sensor 10 can comprise freezing the vortex spin distribution of the sense magnetization 230 by performing a thermal treatment at the interface between the shifting layer 25 and the sense layer 23 (including the spacing layer 26). The freezing of the vortex spin distribution generates a “spring effect” that opposes vortex core polarity switching, and the core polarity switching field is thus shifted at higher magnetic fields.

In the case the TMR sensor 10 comprises a full-bridge or half bridge configuration, the method comprise a step of programming the shifting layer 25 and the reference layer 21 such as to orient the shifting magnetization 250 and the reference magnetization 210, 220 in the same direction, and such the shifting and reference magnetizations 250, 210, 220 in two sensing branches 11-14 within a half bridge have opposite directions. This method step allows for significantly increase the measurement range of the TMR sensor 10.

We also show that other sensor performances can be modulated via adjustment of the sense layer 23 aspect ratio. This solution will lead to improved reproducibility, accuracy, and increased field range.

FIG. 3A shows a graph comparing the magnetization as a function of the external magnetic field for the TMR element 20 in the absence of the shifting layer 25 (curve A) and in the presence of the shifting layer 25 (curve B). In the presence of the shifting layer 25, the vortex core polarity switching field is shifted towards higher negative or positive magnetic fields compared to the TMR element 20 in the absence of the shifting layer 25.

The graph in FIG. 3B compares the response of the TMR sensor 10 in a full bridge configuration where the TMR elements do not comprise the shifting layer 25 (curve A), and where the TMR elements comprises the shifting layer 25 and when the shifting magnetization 250 is in the same direction than the reference magnetization 210, 220, and when the shifting and reference magnetizations 250, 210, 220 in two sensing branches 11-14 within a half bridge have opposite directions (curve B).

FIG. 4 reports the vortex core polarity switching field as a function of the thickness of the shifting layer 25 for TMR elements having a lateral size of 300 nm (curves A) and of 700 nm (curves B). The figure shows that the presence of the shifting layer 25 allows for increasing the vortex core polarity switching field for different aspect ratios of the thickness on the diameter of the sense layer 23. Possible aspect ratios of the sense layer 23 can be between 0.04 and 0.3, or possibly between 0.01 and 1.

For example, the shifting layer 25 is configured to increases the vortex core polarity switching field such that, in comparison with the TMR element 20 not comprising the shifting layer 25, the vortex core magnetization polarity is not switched for an additional external magnetic field above 400 Oe (32 kA/m) in the case of a 4 nm thick shifting layer 25, or above 1000 Oe (80 kA/m) in the case of a 20 nm thick shifting layer 25. Possibly, the shifting layer 25 can be configured to increases the vortex core polarity switching field such that the vortex core magnetization polarity is not switched for an additional external magnetic field above 3000 Oe (239 kA/m), depending on the composition of the shifting layer 25 and of the sense layer 23, the thickness of the shifting layer 25, and the aspect ratio of the TMR element 20.

Due to the distance between the shifting layer 25 and the reference layer 21, the impact of the antiferromagnetically coupling (RKKY coupling) between the first and second reference magnetization 220, 221 on the vortex core polarity switching field is reduced. In other words, the distance between the shifting layer 25 and the reference layer 21 allows for substantially decoupling the shifting layer 25 from the reference layer 21.

Having described exemplary embodiments of the disclosure, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

Reference numbers and symbols

| | |
|---|---|
| 10 | TMR sensor |
| 11-14 | sensing branch |
| 20 | TMR element |
| 21 | reference layer |
| 210 | reference magnetization, |
| | first reference magnetization |
| 211 | first reference sublayer |
| 212 | second reference sublayer |
| 213 | reference coupling layer |
| 22 | tunnel barrier layer |
| 220 | second reference magnetization |
| 23 | sense layer |
| 230 | sense magnetization |
| 231 | vortex core |
| 24 | electrode layer |
| 25 | shifting layer |
| 250 | shifting magnetization |
| 26 | spacing layer |
| 60 | external magnetic field |

What is claimed is:

1. A tunnel magnetoresistance (TMR) element comprising a tunnel barrier layer sandwiched between a reference layer having a pinned reference magnetization and a sense layer having a sense magnetization that is orientable relative to the fixed reference magnetization in the presence of an external magnetic field;
wherein the sense magnetization comprises a stable vortex configuration having a vortex core magnetization polarity that is reversed when a vortex core polarity switching field is applied on the TMR element;
wherein the TMR element further comprises a shifting layer adjacent to the sense layer, the shifting layer having a shifting magnetization and being configured to induce a stray field on the sense layer and increases the vortex core polarity switching field.

2. The TMR element according to claim 1,
wherein the shifting layer is configured to increases the vortex core polarity switching field such that the vortex core magnetization polarity is not switched for an external magnetic field above 400 Oe (32 kA/m), or above 1000 Oe (80 kA/m), or above 3000 Oe (239 kA/m).

3. The TMR element according to claim 1,
wherein the shifting layer comprises a hard magnetic material.

4. The TMR element according to claim 3,
wherein the hard magnetic material comprises a perpendicular ferrimagnetic alloy including at least a rare earth and at least a transition metal.

5. The TMR element according to claim 4,
wherein the rare earth comprises Tb, Gd, Sm and TM and the transition metal comprise Co, Fe, CoFe.

6. The TMR element according to claim 3,
wherein the hard magnetic material comprises a perpendicular ordered alloy, or a multilayered material comprising 3d-4d metals (exhibiting perpendicular magnetic anisotropy.

7. The TMR element according to claim 3,
wherein the hard magnetic material comprises a L1₀ perpendicular ordered magnetic alloy.

8. The TMR element according to claim 3,
wherein the hard magnetic material comprises a permanent magnet based on a rare earth material.

9. The TMR element according to claim 3,
wherein the hard magnetic materials comprises exchange decoupled grains obtained by inserting in the alloy a small amount of Cr, C, Cu, V, or an oxide.

10. The TMR element according to claim 3,
wherein the hard magnetic layer 24 can comprise, or may be made of, an antiferromagnetic material.

11. The TMR element according to claim 1,
further comprising a spacing layer between the hard magnetic layer and the sense layer and configured to regulate the coupling strength between the hard magnetic layer and the sense layer.

12. The TMR element according to claim 1,
wherein the sense layer has a thickness that is greater than 15 nm, preferably between 15 nm and 80 nm or between 15 nm and 100 nm.

13. The TMR element according to claim 1,
having a lateral dimension between 200 nm and 5000 nm.

14. The TMR element according to claim 1,
having an aspect ratio between 0,005 μm and 2 μm.

15. The TMR element according to claim 1,
wherein the reference layer comprises a reference SAF structure including a first reference sublayer having a first reference magnetization, a second reference sublayer having a second reference magnetization, and a reference coupling layer between the first and second reference sublayers;
wherein the coupling layer is configured to produces an antiferromagnetically coupling between the first and second reference magnetization such that the second reference magnetization remains antiparallel to the first reference magnetization.

16. The TMR element according to claim 1,
wherein the magnetization direction of the vortex core is along the out-of-plane axis substantially perpendicular to the plane of the sense layer; and
wherein the reference layer and the shifting layer have a perpendicular magnetic anisotropy such that the reference magnetization and the shifting magnetization are oriented out-of-plane.

17. A TMR sensor comprising a plurality of the TMR elements, each TMR element comprising:
a tunnel barrier layer sandwiched between a reference layer having a pinned reference magnetization and a sense layer having a sense magnetization that is orientable relative to the fixed reference magnetization in the presence of an external magnetic field;
wherein the sense magnetization comprises a stable vortex configuration having a vortex core magnetization polarity that is revered when a vortex core polarity switching field is applied on the TMR element;
wherein the TMR element further comprises a shifting layer adjacent to the sense layer, the shifting layer having a shifting magnetization, the shifting layer being configured to induce a stray field on the sense layer and increases the vortex core polarity switching field.

18. The TMR sensor according to claim 17,
wherein the plurality of the TMR elements are arranged in a full-bridge or half-bridge configuration comprising a plurality of sensing branches, each sensing branch comprising one or a plurality of TMR elements.

19. The TMR sensor according to claim 17,
wherein for each TMR element, the magnetization direction of the vortex core is along the out-of-plane axis substantially perpendicular to the plane of the sense layer; and the reference layer and the shifting layer have a perpendicular magnetic anisotropy such that the reference magnetization and the shifting magnetization are oriented out-of-plane.

20. The TMR sensor according to claim 19,
wherein the shifting magnetization and reference magnetization are oriented in the same direction.

21. The TMR sensor according to claim 20,
wherein the shifting magnetization and reference magnetization in two sensing branches within a half bridge have opposite directions.
